(19) United States
(12) Patent Application Publication
(10) Pub. No.: US 2026/0327022 A1
(43) Pub. Date: Oct. 22, 2026

(54) SUBSTRATE CONVEYING DEVICE

(71) Applicant: FUJI CORPORATION, Chiryu (JP)

(72) Inventor: Takanori TAKAGI, Okazaki-shi (JP)

(73) Assignee: FUJI CORPORATION, Chiryu (JP)

(21) Appl. No.: 19/115,870

(22) PCT Filed: Nov. 1, 2022
(86) PCT No.: PCT/JP2022/040918

§ 371 Date: Mar. 27, 2025

(51) Int. Cl. B65G 49/06; B65G 21/20; B65G 39/06; B65G 39/18

(52) U.S. Cl. CPC B65G 49/064; B65G 21/2072; B65G 39/06; B65G 39/18; B65G 2201/022; B65G 2207/42

(57) ABSTRACT

A board conveying device includes: a pair of guide rails configured to guide both ends in a left-right direction of a board to be conveyed in a conveyance direction, multiple rollers rotatably provided around a central axis in an up-down direction at convey-in positions where the pair of guide rails convey in the board and configured to introduce the board to be conveyed between the pair of guide rails; and a buffer portion configured to buffer an impact when the board comes into contact with outer peripheral surfaces of the rollers.

### TECHNICAL FIELD

The present disclosure relates to a board conveying device.

### BACKGROUND ART

The board conveying device is applied to a board work machine and is used to convey a board in a production line. Patent Literature 1 discloses a configuration in which both ends in a width direction of a board, which is a conveyance target, are guided by a pair of guide rails, and the board is moved in a conveyance direction by rotation of a conveyor belt disposed below the pair of guide rails.

### CITATION LIST

### Patent Literature

Patent Literature 1: JP-A-2014-123597

### BRIEF SUMMARY

### Technical Problem

In such a board conveying device, when the board is conveyed in from upstream in the conveyance direction of the board, the front end portion of the board and the guide rails may collide with each other due to misalignment of the board in the width direction. When a board with low strength is applied for board work, there is a concern that deformation or the like may occur in the board due to collisions with the guide rails.

An object of the present description is to provide a board conveying device that buffers an impact applied to a board when the board is conveyed in and prevents deformation or the like of the board due to conveyance.

### Solution to Problem

The present description discloses board conveying device including: a pair of guide rails configured to guide both ends in a width direction of a board to be conveyed in a conveyance direction; multiple rollers rotatably provided around a central axis in an up-down direction at convey-in positions where the pair of guide rails convey in the board and configured to introduce the board to be conveyed between the pair of guide rails; and a buffer portion configured to buffer an impact when the board comes into contact with outer peripheral surfaces of the rollers.

### Advantageous Effects

With such a configuration, since the impact when the board comes into contact with the outer peripheral surfaces of the rollers is buffered, it is possible to prevent deformation or the like of the board when the board is conveyed in.

### BRIEF DESCRIPTION OF DRAWINGS

FIG. 1 is a schematic view illustrating a configuration of a component mounter to which a board conveying device is applied.

FIG. 2 is a perspective view of a main part of the board conveying device.

FIG. 3 is a side view of the board conveying device.

FIG. 4 is a plan view of a buffer portion as viewed from an IV direction in FIG. 3.

FIG. 5 is a side view as viewed from a V direction in FIG. 4.

FIG. 6 is a perspective view illustrating a buffer portion according to a modification.

### DESCRIPTION OF EMBODIMENTS

A board conveying device will be described with reference to the drawings. In the present embodiment, an example will be described in which the board conveying device is applied to a component mounter, which is a board work machine. The board work machine, to which the board conveying device is applicable, is not limited to the component mounter, and as long as the board work machine performs a predetermined board work on a board, various work machines, such as solder printers and board inspection machines, can be adopted.

### 1. Configuration of Component Mounter 10

Component mounter 10 configures a production line for producing board products together with multiple types of board work machines including, for example, other component mounters 10. The board work machines configuring the production line described above can include a solder printer, a board inspection machine, a reflow oven, and the like.

1-1. Board Conveying Device 11

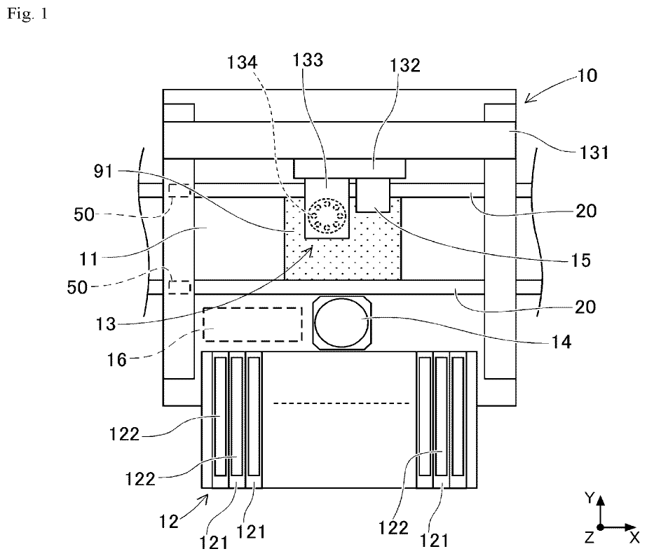

As illustrated in FIG. 1, component mounter 10 includes board conveying device 11. Board conveying device 11 subsequently conveys board 91 in a conveyance direction and positions board 91 at a predetermined position within the mounter. A detailed configuration of board conveying device 11 will be described later.

### 1-2. Component Supply Device 12

Component mounter 10 includes component supply device 12. Component supply device 12 supplies components to be mounted on board 91. In component supply device 12, feeder 122 is set in each of multiple slots 121. A tape feeder that supplies the components to be collectable, for example, by feeding and moving a carrier tape accommodating a large number of components is applied to feeder 122.

### 1-3. Component Transfer Device 13

Component mounter 10 includes component transfer device 13. Component transfer device 13 transfers components supplied by component supply device 12 in a predetermined mounting position on board 91. Component transfer device 13 includes head driving device 131, moving table 132, mounting head 133, and suction nozzles 134. Head driving device 131 moves moving table 132 in a horizontal direction (X direction and Y direction) by a linear motion mechanism. Mounting head 133 is detachably fixed to moving table 132 by a clamp member (not illustrated), and is provided so as to be movable in the horizontal direction within the mounter.

Mounting head 133 rotatably and liftably supports multiple suction nozzles 134. Suction nozzle 134 is a holding member that collects and holds a component supplied by feeder 122. Suction nozzle 134 picks up a component supplied by feeder 122 using supplied negative pressure air. As a holding member to be attached to mounting head 133, a chuck or the like that holds the component by gripping the component can be adopted.

### 1-4. Part Camera 14 and Board Camera 15

Component mounter 10 includes part camera 14 and board camera 15. Part camera 14 and board camera 15 are digital imaging devices having imaging elements, such as CMOS. Part camera 14 and board camera 15 perform imaging based on control signals and send image data acquired by the imaging. Part camera 14 is configured to image a component held by suction nozzle 134 from below. Board camera 15 is provided on moving table 132 to be movable in the horizontal direction integrally with mounting head 133. Board camera 15 is configured to image board 91 from above.

### 1-5. Control Device 16

Component mounter 10 includes control device 16. Control device 16 includes mainly at least one CPU, various memories, and a control circuit. Various data including a control program used for controlling the mounting process and the like are stored in control device 16. The control program is data that indicates the mounting position, the mounting angle, and the component type of the component mounted on board 91 in the mounting process in the scheduled mounting order.

In the mounting process, control device 16 controls the operation of mounting head 133 based on information output from various sensors, the result of image processing, the control program, or the like. As a result, the positions and the angles of multiple suction nozzles 134 supported by mounting head 133 are controlled. As a result, the component held by suction nozzle 134 is mounted at a predetermined mounting position and at a predetermined mounting angle which are instructed by the control program.

### 2. Configuration of Board Conveying Device 11

Board conveying device 11 conveys board 91 conveyed into the upstream end of a conveyance path by the board convey-in device or the external conveyance device along the conveyance path and conveys board 91 to a predetermined stop position. The predetermined stop position of board 91 is set, for example, at the center of the conveyance path in the conveyance direction. The component mounting process by component transfer device 13 is performed on board 91 positioned at the stop position. After the mounting process ends, board conveying device 11 conveys board 91 from the stop position to the downstream end (right end in FIG. 1) and conveys board 91 out of the mounter.

### 2-1. Guide Rail 20

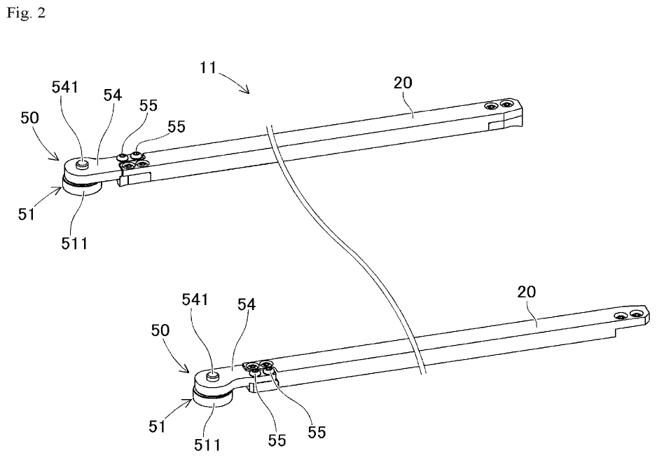

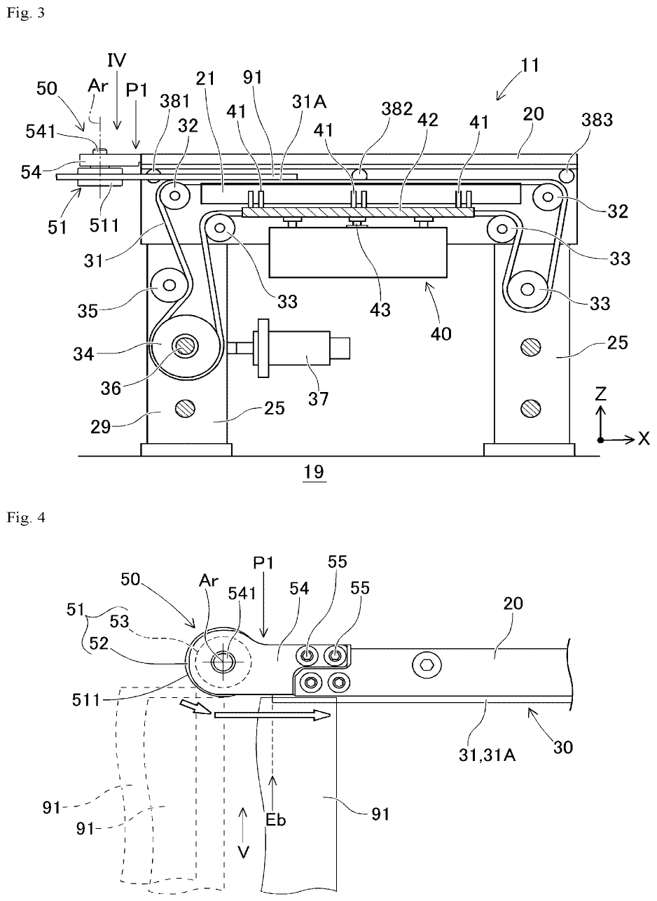

Board conveying device 11 includes pair of guide rails 20 that form the conveyance path of board 91. Pair of guide rails 20 guide both ends in a width direction (a direction perpendicular to the conveyance direction, an up-down direction in FIG. 1, and a front-rear direction in FIG. 3) of board 91 to be conveyed in the conveyance direction (the direction from the lower left to the upper right in FIG. 2, the left-right direction in FIG. 3). Pair of guide rails 20 are installed on the upper side of each of pair of support plates 25, which stand upright on the upper surface of base 19 and are disposed in parallel to be spaced apart from each other. The spacing distance between pair of guide rails 20 is set to correspond to the width dimension of board 91. The spacing distance can be adjusted by the sliding movement of one support plate 25 on the upper surface of base 19.

### 2-2. Drive Section 30

Board conveying device 11 includes drive section 30 that conveys board 91 in the conveyance direction. Drive section 30 includes pair of conveyor belts 31, multiple pulleys, and drive motor 37. Conveyor belt 31 is formed in an endless loop and is disposed along guide rails 20. Conveyor belt 31 is guided to the upper surface of belt guide 21 extending in the conveyance direction on the inner side where pair of guide rails 20 face each other. Two sides along the conveyance direction of board 91 are placed on the upper surfaces of pair of conveyor belts 31.

As illustrated in FIG. 3, conveyor belt 31 engages with pair of front and rear conveyance guide pulleys 32, multiple auxiliary pulleys 33, drive pulley 34, and tensioner pulley 35. Tensioner pulley 35 applies tension to conveyor belt 31 to prevent slack. Drive pulley 34 is supported to rotate integrally with drive shaft 36. Drive shaft 36 extends perpendicular to the conveyance direction and is fixed to the center of each of pair of drive pulleys 34. Drive shaft 36 is rotationally driven by drive motor 37 via a gear mechanism.

Drive motor 37 is, for example, a pulse motor that is controlled by receiving a drive pulse. Drive motor 37 rotates drive shaft 36 to rotate pair of conveyor belts 31 via pair of drive pulleys 34. Accordingly, pair of conveyor belts 31 rotate in synchronization with each other, and hold and convey board 91 placed on the upper surface thereof. Drive motor 37 rotates forward by a predetermined angle due to the input of a positive pulse (drive pulse of positive polarity), and rotates in reverse by a predetermined angle due to the input of a negative pulse (drive pulse of negative polarity). By forward rotation or reverse rotation of drive motor 37 by a predetermined angle, conveyor belt 31 rotates in the advancing direction or the reverse direction by a predetermined unit distance.

### 2-3. Backup Device 40

Board conveying device 11 includes backup device 40. Backup device 40 is disposed below the stop position of board 91, and backup device 40 supports board 91 from below by multiple backup pins 41. Multiple backup pins 41 are provided upright on the upper surface of rectangular plate-shaped backup plate 42. Multiple backup pins 41 are appropriately adjusted in terms of type, quantity, and arrangement positions according to the type of board 91 to be conveyed. Backup plate 42 is configured to move vertically with respect to base 19. Backup plate 42 is driven in lifting and lowering motion by actuator 43, such as a fluid pressure cylinder.

Backup device 40 operates after board 91 is conveyed to the stop position and stopped. Specifically, backup device 40 raises backup plate 42 by the operation of actuator 43. As backup plate 42 is raised, backup pins 41 push board 91 upward. Accordingly, board 91 is clamped and positioned between the upper portions of guide rails 20 and backup pins 41. In this way, backup device 40 functions as a clamping device in board conveying device 11.

After the component mounting process ends, backup device 40 lowers backup plate 42 by the operation of actuator 43. As backup plate 42 is lowered, backup pins 41 move away from board 91 downward. Accordingly, the clamped state of board 91 is released, and board 91 is placed on conveyor belt 31 again. Board 91 is in a state where board 91 can be conveyed to the downstream end of the conveyance path and conveyed out of the mounter.

### 2-4. Board Sensors 381 to 383

Board conveying device 11 includes multiple board sensors 381 to 383 that are disposed at different positions in the conveyance direction and sense the presence or absence of board 91 in the conveyance path. First board sensor 381 is disposed such that the detection position is at the upstream end of the conveyance path where conveyor belt 31 exerts the conveyance function. Second board sensor 382 is disposed such that the detection position is at the stop position set at the center of the conveyance path. Third board sensor 383 is disposed such that the detection position is at the downstream end of the conveyance path. Board sensors 381 to 383 have the same configuration, and for example, photoelectric sensors made up of a light emitting section and a light receiving section can be adopted.

### 2-5. Buffer Unit 50

Board conveying device 11 forms the conveyance path of board 91, which constitutes the production line with the above-described configuration, and conveys and positions board 91 along the conveyance path. Board conveying device 11 conveys board 91 in conjunction with an external conveyance device or the like adjacent upstream. In this case, when board 91 is conveyed in from upstream, the front end portion of board 91 and guide rails 20 may collide with each other due to misalignment of board 91 in the width direction. When board 91 with low strength is applied in the mounting process, there is a concern that deformation or the like may occur in the board due to collisions with guide rails 20.

Here, depending on the type of the mounting process, a glass board having a thickness Ns of 1 mm or less may be adopted as board 91. When such board 91 is conveyed, it is necessary to perform conveyance control to prevent the outer edges from breaking due to an impact applied to board 91. In contrast, for example, it is conceivable to sufficiently reduce the conveyance speed, but such conveyance control causes a reduction in the overall production efficiency.

Therefore, board conveying device 11 of the present embodiment adopts a configuration capable of reducing the impact applied to board 91 when board 91 is conveyed in. Specifically, board conveying device 11 includes buffer unit 50 disposed at the upstream end of guide rails 20. Accordingly, board conveying device 11 prevents deformation and breakage of board 91 due to the conveyance. In the present embodiment, since buffer unit 50 is made up of members symmetrical in a direction perpendicular to the conveyance direction when viewed from above, only one of the members is enlarged and illustrated in FIGS. 4 to 6.

### 3. Detailed Configuration of Buffer Unit 50

### 3-1. Multiple Rollers 51

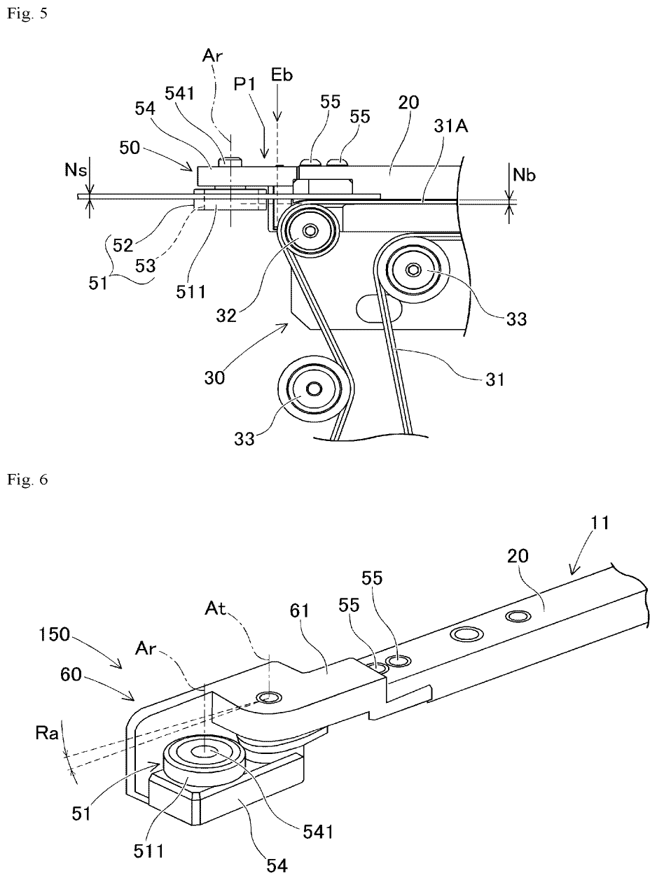

As illustrated in FIG. 2, buffer unit 50 includes multiple rollers 51. As illustrated in FIGS. 4 and 5, rollers 51 are rotatably provided around central axis Ar in the up-down direction at convey-in positions P1 where pair of guide rails 20 convey in board 91. When rollers 51 come into contact with board 91 to be conveyed, rollers 51 receive an external force from board 91 and rotates around central axis Ar. Then, as indicated by a thick arrow in FIG. 4, rollers 51 move board 91 to the center side in the width direction of the conveyance path (lower side in FIG. 4) along outer peripheral surfaces 511 of rollers 51, and introduces board 91 between pair of guide rails 20.

Roller 51 includes outer ring 52 and inner ring 53. Outer ring 52 forms outer peripheral surface 511 in contact with board 91. In the present embodiment, outer ring 52 forms a buffer portion that buffers the impact when board 91 comes into contact with outer peripheral surface 511 of roller 51. Outer ring 52 as the buffer portion is formed of a material having a lower hardness than board 91. When board 91 is a glass board as described above, outer ring 52 is formed of a resin or a rubber. Inner ring 53 is concentric with outer ring 52, and is fitted to an inner peripheral surface of outer ring 52, being configured to rotate integrally. Inner ring 53 is formed in a cylindrical shape and is formed of a material such as metal having a higher hardness than outer ring 52.

### 3-2. Pair of Arms 54

As illustrated in FIG. 2, buffer unit 50 includes pair of arms 54. Arms 54 are fixed to convey-in positions P1 of guide rails 20, respectively, and are formed to extend upstream in the conveyance direction of board 91 (the left-right direction in FIGS. 4 and 5). Arm 54 rotatably supports roller 51 having the configuration described above around central axis Ar. Specifically, arm 54 includes shaft support portion 541 that supports roller 51 by fastening an attachment bolt penetrating inner ring 53 of roller 51 to the arm body. With such a configuration, roller 51 can be exchanged depending on the type of board 91, or the like. Arm 54 is detachably fixed to the upper surface of guide rail 20 by two fixing bolts 55.

### 3-3. Position and Buffering Effect of Roller 51

Roller 51 having outer ring 52 as the buffer portion as described above is disposed at the following position by installing arm 54 at a predetermined position of guide rail 20. Specifically, as illustrated in FIG. 5, roller 51 is disposed such that entire thickness Ns of board 91 to be conveyed falls within an up-down width of roller 51 in the up-down direction. With such a configuration, the contact area between roller 51 and board 91 can be increased, and as a result, the impact applied to board 91 can be further buffered.

As illustrated in FIG. 5, roller 51 is disposed upstream of upstream end Eb of conveyor belt 31 in the conveyance direction of board 91. Accordingly, buffer unit 50 can correct the posture of board 91 (correct the misalignment in the width direction) before board 91 is placed on conveyor belt 31. Further, by placing roller 51 upstream of upstream end Eb, the installation height of roller 51 can be set while preventing the interference with conveyor belt 31, thereby improving the degree of freedom of installation.

As illustrated in FIG. 5, roller 51 is disposed such that portion 31A of conveyor belt 31 that supports board 91 falls within the up-down width of roller 51 in the up-down direction. The “portion 31A that supports board 91” corresponds to a portion located in a section of rotating conveyor belt 31 that supports board 91, that is, a section that extends in the conveyance direction supported by pair of conveyance guide pulleys 32. Roller 51 is disposed such that entire thickness Nb of portion 31A falls within the up-down width of roller 51.

With such a configuration, the lower end of roller 51 is located below the upper surface of portion 31A of conveyor belt 31 that supports board 91. Accordingly, as compared with a configuration in which the lower end of roller 51 is located above the upper surface of conveyor belt 31 in the up-down direction, and a gap is formed between roller 51 and conveyor belt 31, it is possible to prevent board 91 from being caught between roller 51 and conveyor belt 31, thereby making the conveyance process of board 91 more stable.

### 4. Modification of Embodiment

### 4-1. Regarding Buffer Unit 50

In the embodiment, buffer unit 50 includes roller 51 and arm 54, and roller 51 includes soft outer ring 52 as a buffer portion. In contrast, board conveying device 11 may adopt a configuration that buffers the impact applied to board 91 by making roller 51 movable.

Specifically, as illustrated in FIG. 6, buffer unit 150 includes pivot mechanism 60 disposed between arm 54 and guide rail 20 in addition to roller 51 and arm 54. Pivot mechanism 60 includes bracket 61 fixed to guide rail 20. Bracket 61 rotatably supports arm 54 around pivot axis At, which is an up-down axis. Bracket 61 restricts the rotation of arm 54 by a stopper (not illustrated) so that arm 54 pivots within a predetermined angle range Ra.

Further, pivot mechanism 60 returns arm 54 using a spring (not illustrated), so that arm 54 is located at the initial angle in a no-load state. The elastic force applied to arm 54 by the spring is set to a level that enables arm 54 to pivot when board 91 comes into contact with roller 51. In this way, pivot mechanism 60 forms a buffer portion that buffers the impact applied to board 91 by retracting roller 51 due to the impact when board 91 comes into contact with outer peripheral surface 511 of roller 51.

With such a configuration, when board 91 comes into contact with roller 51, arm 54 pivots against the elastic force of the spring due to the external force received by roller 51, and roller 51 temporarily retracts. Accordingly, the impact applied to board 91 is buffered. Thereafter, when board 91 is conveyed downstream in the conveyance direction, the external force that roller 51 receives from board 91 decreases and gradually returns to the initial angle. Accordingly, the posture of board 91 can be corrected (misalignment in the width direction can be corrected), and board 91 can be introduced to the upstream end of guide rails 20.

In buffer unit 150 including such pivot mechanism 60, soft outer ring 52 may be adopted for outer ring 52 of roller 51 to provide further buffering. The above embodiment includes a configuration in which arm 54 is pivoted around pivot axis At to retract roller 51 to the outside of guide rail 20 (the outside in the width direction of board 91). In contrast, the buffer portion need only buffer the impact by retracting roller 51 in a direction intersecting central axis Ar, and for example, a configuration in which roller 51 in contact with board 91 is temporarily retracted downstream in the conveyance direction may be adopted.

### 4-2. Others

In the embodiment, one roller 51 is disposed in arm 54. In contrast, multiple rollers 51 may be disposed in pair of arms 54 along the extending direction of arms 54. Accordingly, during the period when the posture of board 91 is corrected, multiple rollers come into contact with the outer edges of board 91, which can reduce the individual external forces applied to board 91 by multiple rollers 51.

In the embodiment, a glass board is exemplified as board 91. In contrast, board 91 may be harder than the glass board and may have a thickness of 1 mm or more. Since board conveying device 11 is provided with roller 51, arm 54, and buffer portion (outer ring 52 and pivot mechanism 60), it is possible to protect board 91 and correct the posture of board 91 without reducing the conveyance speed. Therefore, it is useful to apply buffer unit 50, 150 when conveying various boards 91.

In the embodiment, the board work machine, to which board conveying device 11 is applied, is the component mounter. In contrast, board conveying device 11 can be applied to various board work machines. The same effect can be obtained from such a configuration.

### REFERENCE SIGNS LIST

10: Component mounter, 11: Board conveying device, 20: Guide rail, 21: Belt guide, 30: Drive section, 31: Conveyor belt, 50, 150: Buffer unit, 51: Roller, 511: Outer peripheral surface, 52: Outer ring (buffer portion), 53: Inner ring, 54: Arm, 60: Pivot mechanism (buffer portion), 61: Bracket, 91: Board, Ar: Central axis, At: Pivot axis, Eb: Upstream end, Nb: Thickness (of conveyor belt), Ns: Thickness (of board), P1: convey-in position

1. A board conveying device comprising:
a pair of guide rails configured to guide both ends in a width direction of a board to be conveyed in a conveyance direction;
multiple rollers rotatably provided around a central axis in an up-down direction at convey-in positions where the pair of guide rails convey in the board and configured to introduce the board to be conveyed between the pair of guide rails; and
a buffer portion configured to buffer an impact when the board comes into contact with outer peripheral surfaces of the rollers.

2. The board conveying device according to claim 1, wherein the buffer portion constitutes each of the outer peripheral surfaces of the rollers and is formed of a material having a lower hardness than the board.

3. The board conveying device according to claim 2, wherein the buffer portion is formed of a resin or a rubber as a material.

4. The board conveying device according to claim 1, wherein the buffer portion buffers the impact by retracting the roller in a direction intersecting the central axis due to the impact when the board comes into contact with the outer peripheral surfaces of the rollers.

5. The board conveying device according to claim 1, wherein the roller is disposed such that an entire thickness of the board to be conveyed falls within an up-down width of the roller in the up-down direction.

6. The board conveying device according to claim 1, further comprising:
a conveyor belt configured to convey the board in the conveyance direction by rotating along the pair of guide rails in a state where the board is placed,
wherein the roller is disposed upstream of an upstream end of the conveyor belt in the conveyance direction of the board.

7. The board conveying device according to claim 6, wherein the roller is disposed such that a portion of the conveyor belt that supports the board falls within an up-down width of the roller in the up-down direction.

8. The board conveying device according claim 1, further comprising:
a pair of arms fixed to the convey-in positions of the pair of guide rails, respectively, and extending upstream in the conveyance direction of the board,
wherein the multiple rollers are rotatably supported by the pair of arms.

9. The board conveying device according to claim 8, wherein the multiple rollers are disposed on each of the pair of arms along an extending direction of the arms.

10. The board conveying device according to claim 1, wherein the board is a glass board having a thickness of 1 mm or less.
